(19) United States
(12) Patent Application Publication
(10) Pub. No.: US 2006/0157770 A1
(43) Pub. Date: Jul. 20, 2006

(54) Metal-to-metal capacitor

(75) Inventor: Chan-Ho Park, Goyang-si (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/315,501

(22) Filed: Dec. 23, 2005

(30) Foreign Application Priority Data
Dec. 23, 2004 (KR) 10-2004-0111037

(51) Int. Cl. H01L 27/108

(52) U.S. Cl. 257/303

(57) ABSTRACT

A metal-to-metal capacitor including a plurality of first metal blocks formed apart from each other in a vertical direction and arranged in an array format, and a plurality of second metal blocks formed apart from each other in a vertical direction and alternately arranged with the array of the first metal blocks. A first plurality of via contacts interconnect the first metal blocks in a vertical direction and are arranged in parallel, and a second plurality of via contacts interconnect the second metal blocks in a vertical direction and are arranged in parallel.

### CROSS-REFERENCE TO RELATED APPLICATION

This application claims priority to and the benefit of Korean Patent Application No. 10-2004-0111037 filed in the Korean Intellectual Property Office on Dec. 23, 2004, the entire contents of which are incorporated herein by reference.

### BACKGROUND OF THE INVENTION

(a) Field of the Invention

The present invention relates to a capacitor used in an analog circuit, and more particularly, to a metal-to-metal (MTM) capacitor having a high lateral capacitance.

(b) Description of the Related Art

Recently, metal-insulator-metal (MIM) capacitors having an efficient capacitance density have been used in various fields. However, in order to compensate some drawbacks in cost and process time for forming the MIM capacitor, a metal-to-metal (MTM) capacitor using a general process has been proposed.

FIG. 1 is a drawing showing a plurality of ideal pole capacitors as one example of a typical MTM capacitor. In addition, FIG. 2 is a lay-out view showing a top view of several rows of the ideal pole capacitors of FIG. 1.

Referring to FIG. 1 and FIG. 2, a plurality of first metal blocks 110 are formed apart from each other in a vertical direction, and a plurality of via contacts 130 are located therebetween. A plurality of second metal blocks 120 are also formed apart from each other in a vertical direction, and a plurality of via contacts 130 are located therebetween. The first metal blocks 110 and the second metal blocks 120 are alternately located in a horizontal direction and are electrically separated by a dielectric layer (not shown).

FIG. 3 is a drawing showing a plurality of actual pole capacitors as one example of the typical MTM capacitor. In addition, FIG. 4 is a lay-out view showing a top view of the actual pole capacitors of FIG. 3. In FIG. 3 and FIG. 4, the same reference numerals as in FIG. 1 and FIG. 2 indicate the same members.

Referring to FIG. 3 and FIG. 4, in the actual pole capacitor, the via contact 130 is formed to have a circular cross-section. In such a pole capacitor, an overlap margin required between the first or second metal block 110 or 120 and the via contact 130 causes an increase of metal block size so that capacitor efficiency per unit area is decreased.

FIG. 5 is a drawing showing a plurality of ideal vertical plate capacitors as another example of the typical MTM capacitor. In addition, FIG. 6 is a lay-out view showing a top view of the ideal vertical plate capacitors of FIG. 5.

Referring to FIG. 5 and FIG. 6, a plurality of first metal lines 510 are formed apart from each other in a vertical direction, and a plurality of via contacts 530 are located therebetween so that a plurality of first vertical plates 510a are formed. A plurality of second metal lines 520 of a stripe-type are also formed apart from each other in a vertical direction, and a plurality of via contacts 530 are located therebetween so that a plurality of first vertical plates 520a are formed. The first vertical plates 510a and the second vertical plates 520a are alternately located in a horizontal direction and are electrically separated by a dielectric layer (not shown).

FIG. 7 is a drawing showing a plurality of actual vertical plate capacitors as another example of the typical MTM capacitor. In addition, FIG. 8 is a lay-out view showing a top view of the actual vertical plate capacitors of FIG. 7. In FIG. 7 and FIG. 8, the same reference numerals as in FIG. 5 and FIG. 6 indicate the same members.

Referring to FIG. 7 and FIG. 8, in the actual vertical plate capacitor, the via contact 530 is formed to have a circular cross-section. In forming such a vertical plate capacitor, the first or second metal line 510 or 520 having the plurality of via contacts 530 cannot be easily formed in parallel in a vertical direction. In addition, the via contacts 530 are formed to have a circular cross-section, and thus, they may not contribute largely to enhancement of parallel capacitance of the vertical plate capacitor.

The above information disclosed in this Background section is only for enhancement of understanding of the background of the invention and therefore it may contain information that does not constitute prior art with respect to the present invention.

### SUMMARY OF THE INVENTION

The present invention has been made in an effort to provide a metal-to-metal capacitor having advantages of a high lateral capacitance.

An exemplary metal-to-metal capacitor according to an embodiment of the present invention includes a plurality of first metal blocks formed apart from each other in a vertical direction and arranged in an array format; a plurality of second metal blocks formed apart from each other in a vertical direction and alternately arranged with the array of the first metal blocks; and a plurality of via contacts interconnecting the first and the second metal blocks in a vertical direction and arranged in parallel.

The plurality of first metal blocks and the plurality of second metal blocks are alternately arranged in at least two directions.

In a further embodiment, a cross-section of the via contact has a shape of a circle.

The exemplary metal-to-metal capacitor can further include dielectric layers formed between the first metal block and the second metal block.

### BRIEF DESCRIPTION OF THE DRAWINGS

FIG. 1 is a drawing showing a plurality of ideal pole capacitors as one example of a typical metal-to-metal (MTM) capacitor.

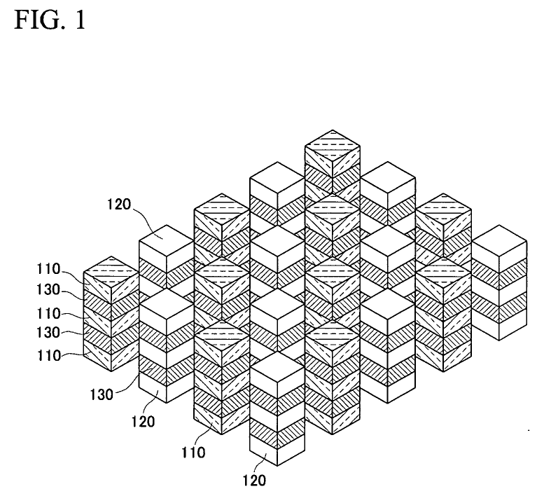

FIG. 2 is a lay-out view showing a top view of the ideal pole capacitors of FIG. 1.

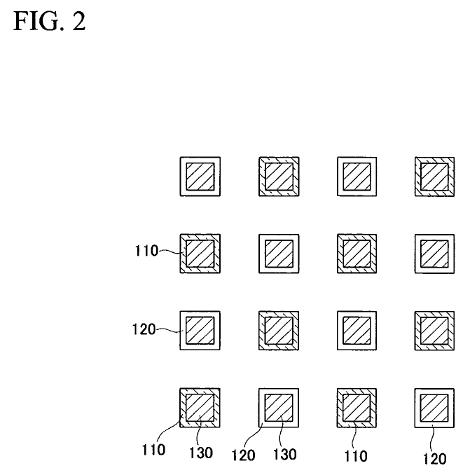

FIG. 3 is a drawing showing a plurality of actual pole capacitors as one example of the typical MTM capacitor.

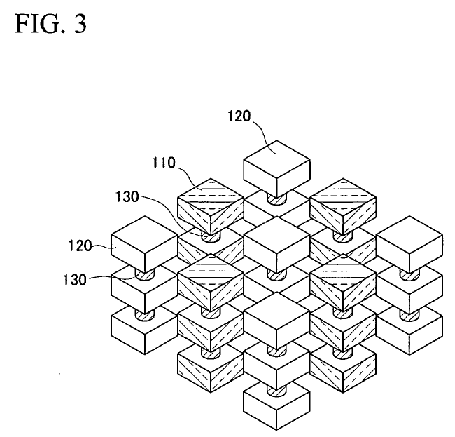

FIG. 4 is a lay-out view showing a top view of the actual pole capacitors of FIG. 3.

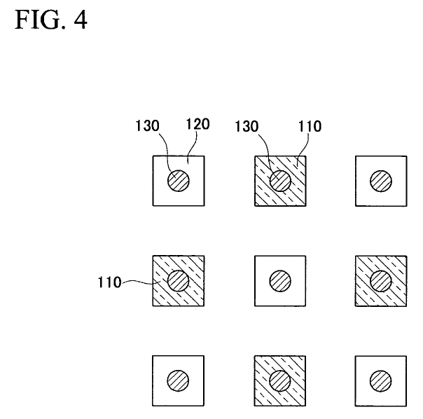

FIG. 5 is a drawing showing a plurality of ideal vertical plate capacitors as another example of the typical MTM capacitor.

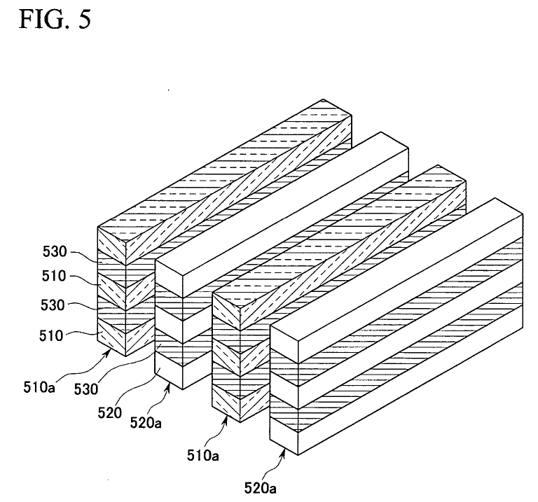

FIG. 6 is a lay-out view showing a top view of the ideal vertical plate capacitors of FIG. 5.

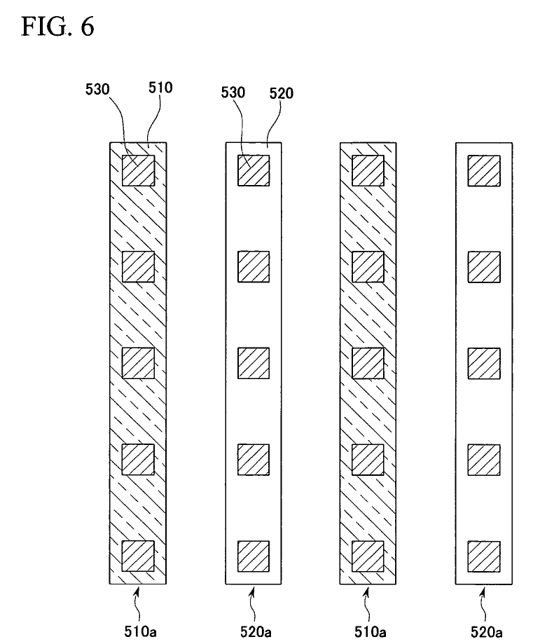

FIG. 7 is a drawing showing a plurality of actual vertical plate capacitors as another example of the typical MTM capacitor.

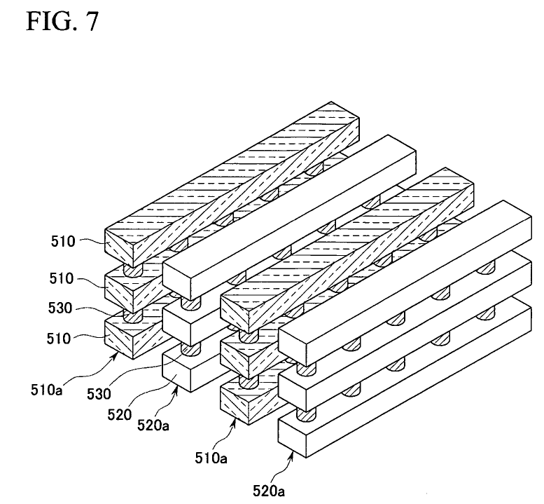

FIG. 8 is a lay-out view showing a top view of the actual vertical plate capacitors of FIG. 7.

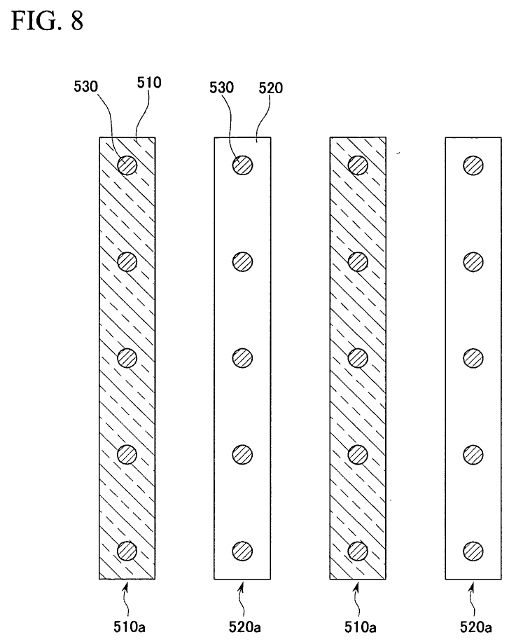

FIG. 9 is a drawing showing a metal-to-metal capacitor according to an exemplary embodiment of the present invention.

FIG. 10 is a lay-out view showing a top view of the metal-to-metal capacitor of FIG. 9.

### DETAILED DESCRIPTION OF THE EMBODIMENTS

An exemplary embodiment of the present invention will hereinafter be described in detail with reference to the accompanying drawings.

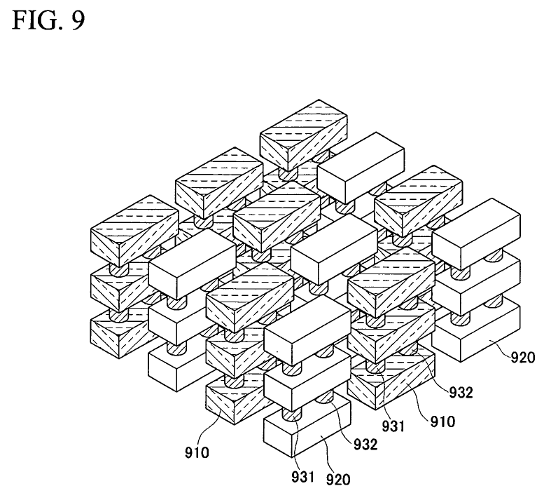

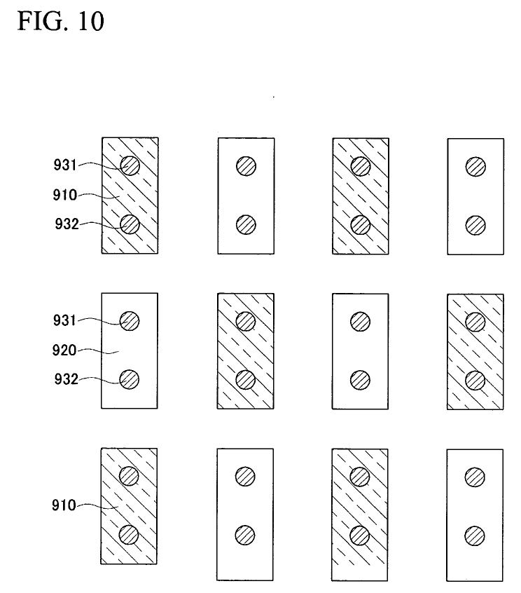

FIG. 9 is a drawing showing a metal-to-metal capacitor according to an exemplary embodiment of the present invention. In addition, FIG. 10 is a lay-out view showing a top view of the metal-to-metal capacitor of FIG. 9.

Referring to FIG. 9 and FIG. 10, the metal-to-metal (MTM) capacitor according to an exemplary embodiment of the present invention has a pole type of structure, and a plurality of first metal blocks 910 are formed apart from each other in a vertical direction. Each pair of the first metal blocks 910 neighboring in a vertical direction are interconnected by a first via contact 931 and a second via contact 932. The first via contact 931 and the second via contact 932 are separated by a dielectric layer (not shown).

In the same way, a plurality of the second metal blocks 920 are also formed apart from each other in a vertical direction, and each pair of the second metal blocks 920 neighboring in a vertical direction are interconnected by a first via contact 931 and a second via contact 932. The first via contact 931 and the second via contact 932 are also separated by a dielectric layer (not shown).

The first metal blocks 910 and the second metal blocks 920 are alternately located in a horizontal direction and are electrically separated from each other by a dielectric layer (not shown). Therefore, each one of the first metal blocks 910 is surrounded by the second metal blocks 920, and in the same way, each one of the second metal blocks 920 is surrounded by the first metal blocks 910. The first via contact 931 and the second via contact 932 are preferably formed to have a circular cross-section.

Such the metal-to-metal capacitor as described above can have a parallel capacitance of high efficiency caused by the pole-type structure. In addition, because each of the first metal blocks 910 is connected by a pair of the first via contact 931 and the second via contact 932 and each of the second metal blocks 920 is connected in the same way, the metal-to-metal capacitor can obtain a fringe capacitance as well as a intrinsic capacitance in a horizontal direction. In such the structure, a width of the metal block can be minimized so that a maximized number of capacitor block arrays can be integrated in a limited area.

As described above, according to an exemplary embodiment of the present invention, the metal blocks in the metal-to-metal capacitor are interconnected by a plurality of via contacts. Therefore, a parallel capacitance of a high capacity can be achieved, while reducing space consumption for an overlap margin between of the via contacts and the metal blocks.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A metal-to-metal capacitor, comprising:
a plurality of first metal blocks formed apart from each other in a vertical direction and arranged in an array format;
a plurality of second metal blocks formed apart from each other in a vertical direction and alternately arranged with the array of the first metal blocks;
a first plurality of via contacts interconnect the first metal blocks in a vertical direction and are arranged in parallel; and
a second plurality of via contacts interconnect the second metal blocks in a vertical direction and are arranged in parallel.

2. The metal-to-metal capacitor of claim 1, wherein via contacts of the first plurality of via contacts have a cross-section that has a shape of a circle.

3. The metal-to-metal capacitor of claim 2, wherein via contacts of the second plurality of via contacts have a cross-section that has a shape of a circle.

4. The metal-to-metal capacitor of claim 1, wherein via contacts of the second plurality of via contacts have a cross-section that has a shape of a circle.

5. The metal-to-metal capacitor of claim 1, further comprising dielectric layers formed between the first metal block and the second metal block.

6. The metal-to-metal capacitor of claim 1, wherein the plurality of first metal blocks and the plurality of second metal blocks are alternately arranged in the array in at least two directions.
